(19) United States
(12) Patent Application Publication
(10) Pub. No.: US 2008/0026542 A1
(43) Pub. Date: Jan. 31, 2008

(54) Method of Manufacturing Semiconductor Device

(76) Inventor: Shim Cheon Man, Yeongdeungpo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/828,793

(22) Filed: Jul. 26, 2007

(30) Foreign Application Priority Data
Jul. 28, 2006 (KR) 10-2006-0071246

(51) Int. Cl. H01L 21/76

(52) U.S. Cl. 438/427; 257/E21.54

(57) ABSTRACT

A method of manufacturing a semiconductor device is provided. According to an embodiment, a first opening is formed on a semiconductor substrate, and a sacrificial layer is formed to fill the first opening. Then, a second opening is formed on a region of the semiconductor substrate having the first opening. The second opening is formed to have a greater width and shallower depth than the first opening. Next, the sacrificial layer is removed, and the first and second openings are filled with insulating material to form a device isolation layer.

### CROSS-REFERENCE TO RELATED APPLICATION

The present application claims the benefit under 35 U.S.C. §119 of Korean Patent Application No. 10-2006-0071246, filed Jul. 28, 2006, which is hereby incorporated by reference in its entirety.

### BACKGROUND

With rapid progress in high speed and high integration trends for semiconductor devices, the demand for improved critical dimensions (CD) has gradually increased according to pattern micronization.

This demand applies to patterns formed on a device region, and also to device isolation layers occupying relatively large areas.

Even though the device region is highly integrated, a predetermined width needs to be obtained to form a semiconductor structure. Therefore, the size of an entire semiconductor device can be minimized by reducing the relatively wide width of a device isolation region.

For this reason, instead of a device isolation layer forming technology that utilizes a local oxidation of silicon (LOCOS) process, an alternative technology utilizing a Shallow Trench Isolation (STI) process is widely used.

When using the STI process, a device can be more minutely manufactured, and also excellent device isolation properties also can be achieved.

A device isolation layer using the STI process has a single damascene structure with a narrow width and a deep depth to achieve electrical isolation between transistors as a device becomes highly integrated. That is, the device isolation layer with the single damascene structure has a relatively large aspect ratio.

### BRIEF SUMMARY

Embodiments of the present invention provide a method of manufacturing a semiconductor device.

In one embodiment, a method of manufacturing a semiconductor device includes: forming a first opening in a semiconductor substrate; forming a sacrificial layer to fill the first opening; forming a second opening in a region of the semiconductor substrate having the first opening, the second opening having a greater width and shallower depth than that of the first opening; removing the sacrificial layer; and filling the first and second openings with an oxide to form a device isolation layer.

The details of one or more embodiments are set forth in the accompanying drawings and the description below. Other features will be apparent from the description and drawings, and from the claims.

### BRIEF DESCRIPTION OF THE DRAWINGS

FIGS. 1-4 are views illustrating a method of forming a device isolation layer according to an embodiment of the present invention.

FIG. 1 is a cross-sectional view after a via hole is formed according to an embodiment.

FIG. 2 is a cross-sectional view after a sacrificial layer is formed in a via hole according to an embodiment.

FIG. 3 is a cross-sectional view after a trench is formed according to an embodiment.

FIG. 4 is a cross-sectional view after a device isolation layer is formed according to an embodiment.

### DETAILED DESCRIPTION

Reference will now be made in detail to embodiments of the present invention, examples of which are illustrated in the accompanying drawings.

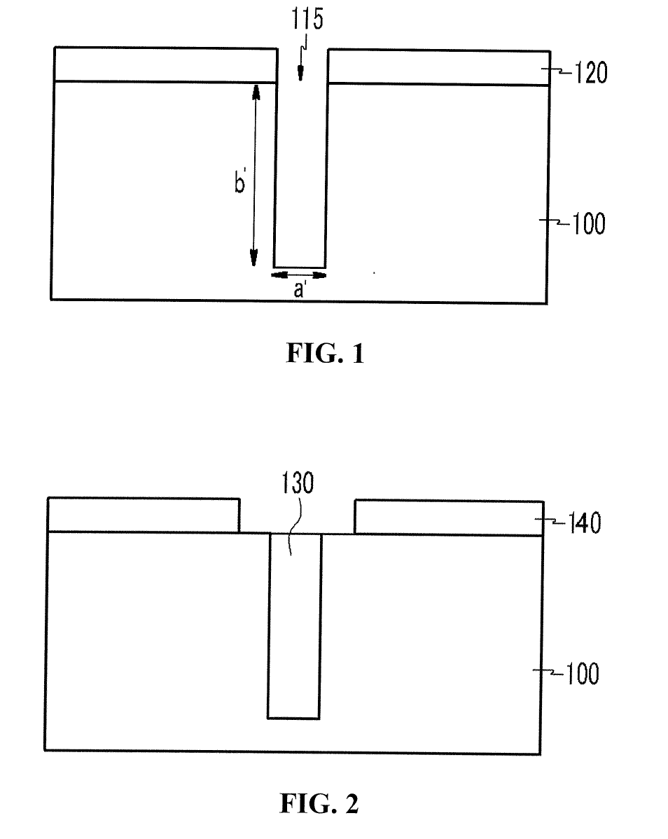

FIGS. 1-4 show a manufacturing method for a semiconductor device according to an embodiment.

First, as illustrated in FIG. 1, a via pattern 120 is formed on a semiconductor substrate 100 using, for example, a photoresist. The semiconductor substrate 100 is etched using the via pattern 120 as a mask in order to form a via hole 115. The etching of the semiconductor substrate 100 can be performed using a reactive ion etching (RIE) method.

A ratio (b′/a′) of the width a′ to the depth b′ of the via hole 115, i.e., an aspect ratio of the via hole 115, may be more than 4.

Next, referring to FIG. 2, the via pattern 120 is removed, and a sacrificial layer 130 is formed in the semiconductor substrate 100 by filling the inside of the via hole 115.

The sacrificial layer 130 can be formed of an organic substance, an inorganic substance, or a combination thereof.

Next, a chemical mechanical polishing (CMP) process can be performed to remove the sacrificial layer 130 from the top surface of the semiconductor substrate 100.

Accordingly, the sacrificial layer 130 only remains in the via hole 115.

After performing the CMP process, a trench pattern 140 is formed on the semiconductor substrate 100 and has a spacing therebetween that is wider than the width of the via pattern 120. The trench pattern 140 exposes the top surface of the sacrificial layer 130 filled in the inside of the via hole 115, and also a portion of the semiconductor substrate 100 around the via hole 115.

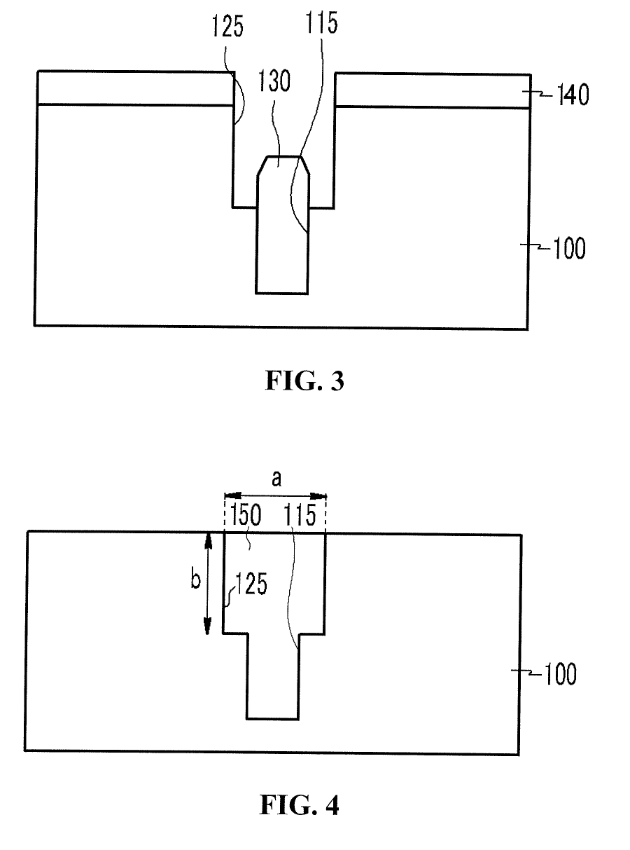

Referring to FIG. 3, the exposed semiconductor substrate 100 and a portion of the sacrificial layer 130 are etched using the trench pattern 140 as a mask to form the trench 125 having the width that is wider than that of the via hole 115. The trench 125 is formed to be shallower than the via hole 115.

At this point, as illustrated in FIG. 3, a portion of the sacrificial layer 130 above the remaining portion of the via hole 115 protrudes in the trench 125 because etching rates of the semiconductor substrate 100 and the sacrificial layer 130 are different from each other.

Then the sacrificial layer 130 remaining in the trench 125 and via hole 115 and the trench pattern 140 are removed. In some embodiments, the trench pattern 140 and the sacrificial layer 130 can be simultaneously removed.

Next, referring to FIG. 4, an insulating material such as an oxide is filled in the trench 125 and the via hole 115 to form a device isolation layer 150.

Accordingly, as illustrated in FIG. 4, an inner wall of the device isolation layer 150 can have a stepped shape in which the width increases in an upward direction.

At this point, a ratio of the width a to the depth b of the trench 125, i.e., an aspect ratio of the trench 125, is below 4.

By using a photolithography process twice, the via hole 115 is formed in the semiconductor substrate 100, and the device isolation layer 150 is formed in the via hole 115 and the trench 125 that is broader than the via hole 115, such that an aspect ratio of the trench 125 may be decreased.

Accordingly, the width of an entrance of the trench 125 in which an oxide is filled is relatively widened.

By widening the entrance of the trench 125, an oxide can be filled in the inside of the trench 125 and the via hole 115 without a void, and thus a device isolation layer 150 free of voids can be formed.

Accordingly, according to an embodiment, electrical property and operational reliability of a semiconductor device are improved.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a semiconductor device, comprising:
forming a first opening in a semiconductor substrate;
forming a sacrificial layer to fill the first opening;
forming a second opening in a region of the semiconductor substrate having the first opening, the second opening having a greater width and shallower depth than that of the first opening;
removing the sacrificial layer; and
filling the first and second openings with insulating material to form a device isolation layer.

2. The method according to claim 1, wherein forming the first opening comprises:
forming a first mask pattern on the semiconductor substrate;
etching the semiconductor substrate using the first mask pattern as an etch mask to form the first opening; and
removing the first mask pattern.

3. The method according to claim 2, wherein forming the first mask pattern comprises developing and exposing a photoresist.

4. The method according to claim 2, wherein etching the semiconductor substrate comprises performing a reactive ion etching process.

5. The method according to claim 1, wherein forming the second opening comprises:
forming a second mask pattern on the semiconductor substrate, the second mask pattern exposing an upper surface of the sacrificial layer and a portion of the semiconductor substrate around the sacrificial layer;
etching the semiconductor substrate using the second mask pattern as an etch mask to form the second opening; and
removing the second mask pattern.

6. The method according to claim 5, wherein removing the sacrificial layer and removing the second mask pattern are simultaneously performed.

7. The method according to claim 1, wherein the first opening comprises a via hole and the second opening comprises a trench.

8. The method according to claim 1, wherein the second opening has a width-to-depth ratio of less than 4.

9. The method according to claim 1, wherein the first opening has a width-to-depth ratio of more than 4.

10. The method according to claim 1, wherein the sacrificial layer comprises an organic substance, an inorganic substance, or a combination thereof.

11. The method according to claim 1, wherein forming the sacrificial layer comprises:
depositing the sacrificial layer on the semiconductor substrate including the first opening; and
removing the sacrificial layer from the surface of the semiconductor substrate.

12. The method according to claim 11, wherein removing the sacrificial layer comprises performing a chemical mechanical polishing process.
